(19) United States
(12) Patent Application Publication
(10) Pub. No.: US 2008/0085598 A1
(43) Pub. Date: Apr. 10, 2008

(54) METHOD OF PATTERNING CONTACT HOLES

(76) Inventors: Wai-Kin Li, Beacon, NY (US); Kuang-Jung Chen, Poughkeepsie, NY (US); Wu-Song Huang, Poughkeepsi, NY (US)

Correspondence Address: FREDERICK W. GIBB, III;Gibb & Rahman, LLC, 2568-A RIVA ROAD, SUITE 304, ANNAPOLIS, MD, 21401, US

(21) Appl. No.: 11/538,475

(22) Filed: Oct. 4, 2006

(51) Int. Cl. H01L 21/467

(52) U.S. Cl. 438/637; 438/736; 438/725

(57) ABSTRACT

A method forms a blocking mask first and then patterns a contact hole mask over the blocking mask to provide a method of patterning contact holes in a substrate. This method first forms a blocking layer on the substrate and then patterns the blocking layer to have first openings to form the blocking mask. Next, the method forms the contact hole layer on the substrate and the blocking mask, and patterns the contact hole layer to have regularly spaced second openings to form the contact hole mask. The patterning of the contact hole layer does not affect the blocking mask and the contact hole mask is aligned directly over the blocking mask. Then, the substrate is patterned through the first openings and the second openings such that the substrate is patterned only where the first openings and the second openings align with each other. Thus, the blocking mask controls which of the regularly spaced second openings will transfer into the substrate.

### BACKGROUND AND SUMMARY

The embodiments of the invention generally relate to methods for patterning contact holes in a substrate.

Because of various issues, such as depth of focus (DOF) and exposure latitudes (EL) of photolithogrphy, it is sometimes difficult to print a contact hole resist mask with closely spaced adjacent open holes to the sub-quarter micron range. It is fairly straightforward to print a complete pattern of regularly spaced openings on a substrate; however, when the regular pattern needs to be interrupted, so that the regularly spaced pattern of contact hole openings is no longer completely regular, it can be very difficult to properly form the contact hole resist mask with any advanced off-axis illuminations system. This difficulty has been shown in the past where the non regular isolated contact holes usually exhibit relatively smaller DOF and EL.

One inventive solution that allows for an irregular pattern of contact holes to be formed from an otherwise regular pattern of holes, begins by forming a contact hole resist mask with a complete pattern of regularly spaced holes. This method then covers the contact hole mask with a patterned blocking mask which only permits selected ones of the regularly spaced openings to transfer to the underlying substrate. However, in order to prevent the contact hole mask from being damaged during the forming and patterning of the blocking mask, the contact hole mask is cross-linked before the blocking mask is formed over the contact hole mask. One disadvantage of such a process is that the cross-linking process undesirably causes deformation of the size of the contact hole openings.

Therefore, another inventive solution comprises a method that forms the blocking mask first and then patterns the contact hole mask over the blocking mask to provide a better method of patterning the contact holes in the substrate. More specifically, this method first forms a blocking layer on the substrate and then patterns the blocking layer to have first openings to form the blocking mask. If desired, the blocking mask can be cross-linked at this point. Next, the method forms the contact hole layer on the substrate and the blocking mask, and patterns the contact hole layer to have regularly spaced second openings to form the contact hole mask.

The patterning of the contact hole layer does not affect the blocking mask and the contact hole mask is aligned directly over the blocking mask. Then, the substrate is patterned through the first openings and the second openings such that the substrate is patterned only where the first openings and the second openings align with each other. Thus, the blocking mask controls which of the regularly spaced second openings will transfer into the substrate. In one embodiment, the blocking mask transfers two adjacent regularly spaced second openings into the substrate and transfers a third regularly spaced second opening that is separated from the two adjacent regularly spaced second openings by the distance of a single one of the regularly spaced second openings.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a flow diagram illustrating a preferred method of an embodiment of the invention; and

FIG. 2 illustrates a schematic diagram of a blocking mask and a contact hole mask combined into a combined mask.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, one inventive solution to the need to form an irregular pattern of contact hole openings from an otherwise regular pattern of openings, begins by forming a contact mask with a complete pattern of regularly spaced openings. This method then covers the contact hole mask with a patterned blocking mask which only permits selected ones of the regularly spaced openings to transfer to the underlying substrate. However, in order to prevent the contact hole mask from being damaged during the forming and patterning of the blocking mask, the contact hole mask is cross-linked before the blocking mask is formed over the contact hole mask. As mentioned above, one disadvantage of such a process is that the cross-linking process can undesirably cause deformation of the size of the contact hole openings.

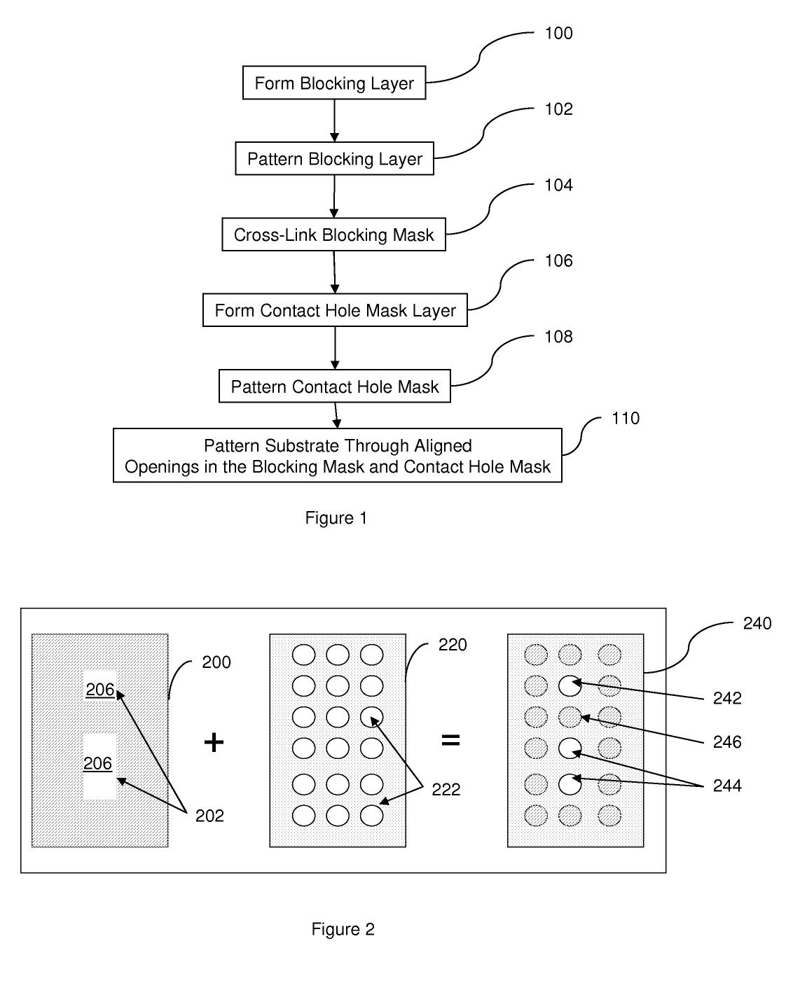

Therefore, another inventive solution that is shown in FIGS. 1 and 2, comprises a method that forms the blocking mask 200 first, and then patterns the contact hole mask 220 over the blocking mask 200 to provide a better method of patterning the contact holes in the substrate 206 using the combined masks 240. The openings 202 in the blocking mask 200 reveal the underlying substrate 206.

This method first forms the blocking layer 200 on the substrate 206 (in item 100) and then patterns the blocking layer to have first openings 202 to form the blocking mask 200 in item 102. If desired, the blocking mask can be cross-linked at this point 104. For example, the blocking mask can be hard baked or subjected to a silylation process. The hard baked resist can be a positive tone resist which has minimum deformation of the size of the openings during thermal cross-linking process. This low deformation positive tone resist can be designed with the incorporation of cross-linking functionality which provides cross-linking before the thermal deprotection of the protecting groups on the resist polymers. Alternatively, the cross-linking process 104 can be omitted if, for example, a negative tone photoresist blocking mask is utilized that is different than the tone of the contact hole mask 220. Negative tone photoresists are cross-linked by definition and are generally not used for the contact hole masks because of the problem of undesirable artifacts, commonly known as stringers. To eliminate cross-linking process 104 and use positive tone resists for blocking layer 200 and contact hole layer 220, the solvents of these two resists for forming these two layers should be sufficiently different to prevent intermixing between these two layers. The difference of the sensitivities of these two positive tone resists should be large enough such that the step of printing of the contact holes on the contact hole layer 220 would not print holes on the blocking layer 200.

Next, the method forms the contact hole layer 220 on the substrate 206 and the blocking mask 200 in item 106, and patterns the contact hole layer to have regularly spaced second openings 222 to form the contact hole mask 220 in item 108. The contact hole mask 220 is not cross-linked so as to avoid increasing the size of the openings 222 within the contact hole mask 220. The patterning of the contact hole layer 108 does not affect the blocking mask and the contact hole mask is aligned directly over the blocking mask. In addition, the size of the contact hole openings can be further reduced with thermal flow processes or chemical shrinkage processes.

Then, the substrate 206 is patterned through the first openings 202 and the second openings 222 in item 110, such that the substrate 206 is patterned only where the first openings 202 and the second openings 222 align with each other. Thus, the blocking mask 200 controls which of the regularly spaced second openings 222 will transfer into the substrate 206.

In the embodiment shown in FIG. 2, the combined blocking mask and contact hole mask 240 transfers two adjacent regularly spaced second openings 244 into the substrate and transfers a third regularly spaced second opening 242 that is separated from the two adjacent regularly spaced second openings by the distance of a single one (246) of the regularly spaced second openings. As can be seen in FIG. 2, the only contact holes 242, 244 that are transferred into the substrate 206 are those where the openings in the blocking mask 200 and the contact hole mask 220 align and the remainder of the evenly spaced contact hole openings 220 are blocked by the blocking mask 240.

Therefore, the embodiments herein provide a solution that allows the regularly spaced openings of a contact hole mask to be selectively blocked using a blocking layer, without requiring the cross-linking of the contact hole mask. Therefore, the embodiments herein do not produce undesirable artifacts, or unnecessarily increase the size of the openings within the contact hole mask.

The contact hole openings can be isolated hole opening such as 242, or a group of contact hole openings adjacent to each other such as 244. The amount of contact holes adjacent to each other can be two or more. The adjacent holes can be arranged to form any shape. The typical shapes are line shapes, L shapes, U shapes, O shapes, rectangular shapes, square shapes, and any of their combinations. The combined blocking mask and contact hole mask 240 may contain only one isolated hole opening, many isolated hole openings, only adjacent hole openings or both isolated and adjacent hole openings. The distance between the isolated hole opening (242) and adjacent hole openings (244) can be a single one (246) or more. The distance between isolated hole openings can be a single one or more. Similarly, the adjacent hole openings can be separated by one or more. The shapes of the adjacent hole openings in the combined blocking mask and contact hole mask 240 may contain only one shape or contain many different shapes.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A method of patterning contact holes in a substrate comprising:
forming a blocking layer on said substrate;
patterning said blocking layer to have first openings to form a blocking mask;
forming a contact hole layer on said substrate and said blocking mask;
patterning said contact hole layer to have regularly spaced second openings to form a contact hole mask; and,
patterning said substrate through said first openings and said second openings such that said substrate is patterned only where said first openings and said second openings align with each other,
wherein said blocking mask controls which of said regularly spaced second openings will transfer into said substrate.

2. The method according to claim 1, wherein said patterning of said contact hole layer does not affect said blocking mask.

3. The method according to claim 1, wherein said contact hole mask is aligned directly over said blocking mask.

4. The method according to claim 1, wherein said blocking layer comprises a negative tone resist.

5. The method according to claim 1, wherein said blocking layer comprises a positive tone resist.

6. A method of patterning contact holes in a substrate comprising:
forming a blocking layer on said substrate;
patterning said blocking layer to have first openings to form a blocking mask;
forming a contact hole layer on said substrate and said blocking mask;
patterning said contact hole layer to have regularly spaced second openings to form a contact hole mask; and
patterning said substrate through said first openings and said second openings such that said substrate is patterned only where said first openings and said second openings align with each other,
wherein said blocking mask controls which of said regularly spaced second openings will transfer into said substrate such that said blocking mask transfers isolated hole opening into said substrate or transfers two or more adjacent hole openings arranged in a shape selected from the group consisting of line shapes, L shapes, U shapes, O shapes, rectangular shapes, square shapes, and any of their combinations thereof.
